(19) United States
(12) Patent Application Publication
(10) Pub. No.: US 2005/0174140 A1
(43) Pub. Date: Aug. 11, 2005

(54) Thin film transistor array inspection device

(75) Inventor: Kota Iwasaki, Hadano-shi (JP)

Correspondence Address: HAUPTMAN KANESAKA BERNER PATENT AGENTS, SUITE 300, 1700 DIAGONAL RD, ALEXANDRIA, VA, 22314-2848, US

(73) Assignee: SHIMADZU CORPORATION, Kyoto (JP)

(21) Appl. No.: 11/039,931

(22) Filed: Jan. 24, 2005

(30) Foreign Application Priority Data
Jan. 30, 2004 (JP) 2004-022820

(51) Int. Cl. G01R 31/00

(52) U.S. Cl. 324/770

(57) ABSTRACT

A TFT array inspection device inspects a TFT array by irradiating a TFT substrate with a charged particle beam and detecting secondary electrons produced from a pixel electrode of the TFT substrate by irradiation of the charged particle beam. The TFT array inspection device includes a charged particle beam control device for changing at least one of a size and a shape of the charged particle beam in accordance with at least one of a specification of the pixel electrode and a number of detection points on the pixel electrode.

### BACKGROUND OF THE INVENTION AND RELATED ART STATEMENT

The present invention relates to a TFT array inspection device, and in particular, to an inspection device for inspecting a defective pixel and performance of a thin film transistor array (TFT array) used for a liquid crystal display, an organic EL display, and the like, using a charged particle beam and measurement data.

As a configuration in which TFTs (thin film transistors) are arranged in an array form, for example, there is a liquid crystal substrate used for a flat panel display (FPD) of a liquid crystal display and the like. A liquid crystal display formed of the TFTs has a basic structure of a liquid crystal panel in which a liquid crystal is filled in a space between one glass substrate on which the TFTs and pixel electrodes are formed and another glass substrate on which opposing electrodes are formed.

The glass substrate has a plurality of panels formed with a common fabrication process of integrated circuits, and the panels are constituted by a plurality of pixels arranged in a matrix pattern. Each pixel has a pixel electrode, a storage capacitor, and a thin film transistor (TFT). The pixel electrode is formed of a light-transmitting material such as ITO (indium-tin oxide).

FIG. 9 shows an example of a configuration of a thin film transistor (TFT) for a display. The configuration is formed of thin film transistors (TFT) a, pixel electrodes b, odd number data lines e, even number data lines f, odd number gate lines c, even number gate lines d, and common lines g. The data lines e and f and the gate lines c and d are intersecting, but are not electrically connected. The TFTs a are connected to the data lines e and f and the gate lines c and d, respectively. Some of TFT arrays may not have the common lines g. In that case, the pixel electrodes b are connected to adjacent gate lines via electrostatic capacitors. In order for the display to function properly, a voltage needs be applied to the pixel electrodes so that each TFT functions normally and displays an image.

In order to determine whether a voltage is normally applied to the pixel electrodes, it is possible to utilize the principle that kinetic energy of a secondary electron produced when a pixel electrode is irradiated with a charged particle changes according to a voltage of the pixel electrode (see U.S. Pat. No. 5,982,190). Such a voltage contrast technology of the charged particle can determine a state of the TFT on a substrate without contact, and has an advantage of low cost as compared with a conventional inspection method using a mechanical probe. It is also possible to inspect faster as compared with an optical inspection method.

The principle of the voltage contrast technology based on an amount of secondary electrons will be explained next. An amount of secondary electrons emitted from each pixel electrode of a TFT substrate and reaching a detector is dependent on a polarity of a voltage of the pixel electrodes of the TFT substrate. For example, when the pixel electrodes of the TFT substrate are driven to positive potential (plus), the secondary electrons produced by irradiation of the pixel electrodes with the charged particles have negative potential (minus) charge, so that the secondary electrons are drawn into the pixel electrodes. As a result, the amount of the secondary electrons reaching the secondary electron detector is reduced.

On the other hand, when the pixel electrodes of the TFT substrate are driven to negative potential (minus), the secondary electrons produced by irradiation of the pixel electrodes with the charged particles have negative potential (minus) charge, so that the secondary electrons are repelled from the pixel electrodes. As a result, the secondary electrons produced from the pixel electrodes reach the secondary electron detector without being reduced.

As described above, when one of a negative voltage and positive voltage, or no voltage is applied to the pixel electrodes, the amount of the detected secondary electrons produced from the pixel electrodes is influenced by the polarity of the voltage of the pixel electrodes. Accordingly, it is possible to measure a waveform of the secondary electron corresponding to a voltage waveform of the pixel electrodes. That is, it is possible to determine the voltage waveform of the pixel electrodes indirectly. Accordingly, the voltage waveform is compared with a secondary electron waveform estimated in advance, so that it is possible to determine whether a voltage is normally applied to the pixel electrodes.

The pixel electrode of the TFT array usually has a rectangular or polygonal shape and a size of several tens to several hundreds of microns. The size of the pixel electrode is determined according to a size and a resolution of a display as a finished product. Therefore, when a TFT array inspection device inspects plural types of TFT arrays having different sizes and resolutions, it is necessary to inspect the respective pixel electrodes having different sizes.

In a conventional TFT array inspection device, a TFT substrate is scanned with a charged particle beam having a specific diameter, and the secondary electrons are detected at a specific timing to obtain a secondary electron waveform. FIGS. 10(a) to 10(e) are views for explaining a process of scanning the charged particle beam and a process of detecting the secondary electrons. In this case, one pixel electrode is detected at four detection points. Each of the pixel electrodes is represented by coordinates, in which horizontal coordinates are represented by α, β, γ, . . . , and vertical coordinates are represented by 1, 2, . . . .

The TFT array is scanned horizontally with the charged particle beam, and the secondary electrons are detected at a timing in which two points are detected while the charged particle beam scans one pixel electrode. FIG. 10(a) shows a position of a detection point α1-1 as the first point on a pixel electrode at a coordinate position (α1), and FIG. 10(b) shows a position of a detection point α1-2 as the second point. The charged particle beam moves to a pixel electrode at the adjacent coordinate position (β1), and a detection point β1-1 as the first point on the pixel electrode is detected (FIG. 10(c)).

After the charged particle beam scans the first line of the TFT substrate, the second line is scanned. The secondary electrons are detected at the detection points on the pixel electrode in the same manner (FIGS. 10(d) and 10(e)). The scan and detection of the secondary electrons at a specific timing are repeated, thereby detecting the four points on the pixel electrodes. FIG. 11(a) is an example of a scan signal of the charged particle beam, and FIG. 11(b) is an example of a timing signal for detecting the secondary electron signals. The timing signal may be changed relative to the scan signal, thereby changing the number of the detection points on one pixel electrode.

FIGS. 12(a) to 12(c) are schematic views for explaining a relationship between the pixel electrode on the TFT substrate and an irradiation area of the charged particle beam. In this case, as an example, the charged particle beam is irradiated at four points on each pixel electrode. The number of positions irradiated with the charged particle beam on one pixel electrode is not limited to four points, and may be any number such as six or eight.

FIG. 12(a) shows an example in which a size of the charged particle beam is sufficiently smaller than the pixel electrodes 21 and 22, and an area 23a irradiated by the charged particle beam covers just a part of the pixel electrodes 21 and 22. In this case, an emission rate of the secondary electrons may vary depending on the position irradiated by the charged particle beam, so that the amount of the secondary electrons may fluctuate. On the other hand, it is less likely that the irradiation area 23a of the charged particle beam is accidentally located on an adjacent pixel electrode. Accordingly, even if the charged particle beam is irradiated on a specific position with low precision, it is possible to obtain the secondary electrons produced from the pixel electrode of target. For example, the irradiation area 23a of the charged particle beam can be precisely located on the pixel electrode 21 or 22. Accordingly, when the pixel electrode 21 is a normal pixel electrode and the pixel electrode 22 is a defective pixel electrode, it is possible to precisely determine the defective pixel electrode.

FIG. 12(b) shows an example in which the positions irradiated by the charged particle beam are arranged adjacent and not overlapped. In this case, an irradiation area 23b of the charged particle beam covers a large part of the pixel electrodes 21 and 22. Accordingly, it is less likely that the emission rate of the secondary electrons on the pixel electrodes has a large influence. As a result, there is less fluctuation in the amount of the detected secondary electrons emitted from each pixel electrode, thereby improving precision of detection.

On the other hand, when the charged particle beam is irradiated on a specific position with low precision, the irradiation area 23b of the charged particle beam may cover an adjacent pixel electrode. When the adjacent pixel electrodes 21 and 22 are a normal and a defective pixel electrode, the secondary electrons from the normal pixel electrode may be mixed with the secondary electrons from the defective pixel electrode. As a result, it is difficult to discriminate between the normal pixel and the defective pixel.

FIG. 12(c) shows an example in which a size of the charged particle beam is large and an irradiation area 23c of the charged particle beam extends out of the pixel electrodes 21 and 22. In this case, the secondary electrodes from an adjacent pixel electrode are always mixed. Accordingly, it is even more difficult than the case in FIG. 12(b) to discriminate between a normal pixel and a defective pixel. On the other hand, it is possible to irradiate an entire surface of the pixel electrode with the charged particle beam.

In the conventional TFT array inspection method using the charged particle beam, a size of the charged particle beam is constant. Accordingly, it is difficult to detect a defect with high precision due to the relationship between the irradiation area of the charged particle beam and the pixel electrode as mentioned above. Further, when a shape of the pixel electrodes is changed, it is difficult to detect a defect with constant precision due to a difference in shapes between the irradiation area of the charged particle beam and the pixel electrode.

In view of the problems described above, an object of the present invention is to provide a TFT array inspection device for detecting a defect with constant precision even when a size of a pixel electrode of a TFT substrate is changed.

Further objects and advantages of the invention will be apparent from the following description of the invention.

### SUMMARY OF THE INVENTION

In order to attain the objects described above, according to the present invention, a charged particle beam having an optimal size and shape is irradiated on a pixel electrode according to a size and setting condition of the pixel electrode. Accordingly, it is possible to detect a defect of a TFT array without an influence of a size and shape of the pixel electrode of the TFT array.

According to the present invention, a TFT array inspection device irradiates a TFT substrate with a charged particle beam to produce secondary electrons from the pixel electrode of the TFT substrate. The secondary electrons are detected for inspecting the TFT array. The TFT array inspection device comprises a charged particle beam control device for changing a size and/or shape of the charged particle beam in accordance with a specification of the pixel electrode and/or a number of detection points on one pixel electrode.

The charged particle beam control device comprises a data table storing beam data for setting the size and/or shape of the charged particle beam in correspondence with the specification of the pixel electrode and/or the number of the detection points on one pixel electrode. The beam data is read from the data table based on the specification of the pixel electrode and/or the number of the detection points on one pixel electrode, so that the size and/or shape of the charged particle beam is controlled based on the beam data.

The specification of the pixel electrode includes a parameter of a size and/or a resolution of the TFT substrate, as well as the setting condition of the pixel electrode.

The data table stores the beam data for defining the size of the charged particle beam in advance according to the size and the resolution of the TFT substrate, so that the charged particle beam generated from a charged particle source is controlled to focus into the beam size. The data table also stores the beam data for defining the shape of the charged particle beam in advance according to the setting condition of the pixel electrode, so that the charged particle beam generated from the charged particle source is controlled to form the beam shape. The data table further stores the beam data for defining the beam size of the charged particle beam in advance according to the number of the detection points on one pixel electrode, so that the charged particle beam generated from the charged particle source is controlled to focus into the beam size.

The specification of the pixel electrode including the parameter can be specified according to a type of TFT substrate. The data table can store the size and shape of the charged particle beam according to the type of TFT substrate. The beam data is read from the data table for controlling the charged particle beam to have the size and shape according to the type of TFT substrate.

When the charged particle beam has a round beam shape, the charged particle beam control device changes the beam size in accordance with the specification of the pixel electrode and/or the number of the detection points on one pixel electrode.

According to the present invention, even when the size of the pixel electrode of the TFT is changed, it is possible to detect a defect with constant precision without an influence of the change.

### BRIEF DESCRIPTION OF THE DRAWINGS

FIG. 1 is a block diagram for explaining a general configuration of a TFT array inspection device according to an embodiment of the present invention;

FIGS. 2(a) to 2(d) are schematic diagrams for explaining a relationship between a beam size and beam shape, and the number of detection points and a specification of a pixel electrode;

FIGS. 3(a) to 3(c) are schematic diagrams showing examples of a beam size and a beam shape defined according to a substrate type;

FIGS. 4(a) and 4(b) are views showing examples of a data table;

FIGS. 5(a) to 5(f) are schematic diagrams for explaining examples of the size of a charged particle beam in accordance with the number of the detection points and the substrate type;

FIGS. 6(a) to 6(c) are schematic diagrams for explaining examples of the beam shape of the charged particle beam in accordance with a setting condition of the pixel electrode;

FIG. 7 is a block diagram of a configuration for setting the beam size and/or beam shape for a TFT substrate as an object of inspection;

FIGS. 8(a) and 8(b) are schematic diagrams for explaining a process of recording detection signals of secondary electrons;

FIG. 9 is a view showing a configuration of a thin film transistor (TFT) for a display;

FIGS. 10(a) to 10(e) are schematic diagrams for explaining a process of scanning a charged particle beam and detecting secondary electrons;

FIGS. 11(a) and 11(b) are charts showing examples of a scan signal of the charged particle beam and a timing signal for detecting the secondary electrons; and

FIGS. 12(a) to 12(c) are schematic diagrams for explaining a relationship between a pixel electrode on a TFT substrate and an irradiation area of the charged particle beam.

### DETAILED DESCRIPTION OF PREFERRED EMBODIMENTS

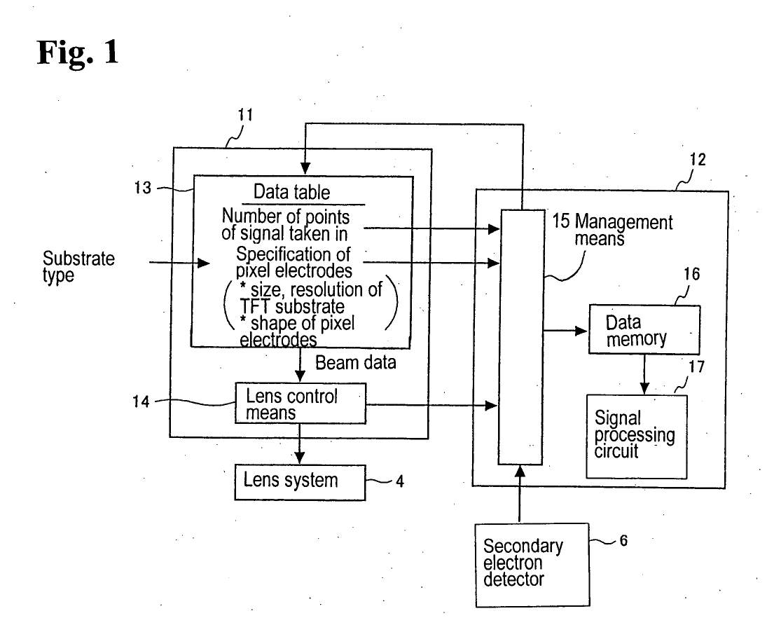

Hereunder, embodiments of the present invention will be explained with reference to the accompanying drawings. FIG. 1 is a block diagram for explaining a general configuration of a TFT array inspection device according to an embodiment of the present invention. In FIG. 1, a TFT substrate as an object of inspection, a charged particle beam source for irradiating a charged particle beam on the TFT substrate, a device for scanning the charged particle beam, and a chamber are omitted.

In FIG. 1, the charged particle beam source (not shown) generates the charged particle beam. The charged particle beam is formed in a specific beam shape with a specific beam size by an electrostatic lens (magnetic lens) 4, and is radiated on the TFT substrate (not shown). Secondary electrons are emitted from the TFT substrate irradiated with the charged particle beam, and are detected by a secondary electron detector 6. A signal processing device 12 processes a secondary electron signal detected at the secondary electron detector 6, thereby inspecting a defect on a pixel electrode.

A charged particle beam control device 11 controls the electrostatic lens (magnetic lens) 4 to form the charged particle beam in a specific beam shape with a specific beam size. The charged particle beam control device 11 comprises a data table 13 for storing beam data for shaping the charged particle beam. The lens control device 14 reads the beam data from the data table 13 and drives the electrostatic lens (magnetic lens) 4 to shape the charged particle beam into the specific beam shape with the specific beam size. The beam size and/or beam shape are defined in advance corresponding to the number of detection points and a specification of the pixel electrode, and the data table 13 stores the beam data for controlling the electrostatic lens (magnetic lens) to obtain the beam sizes and/or beam shape.

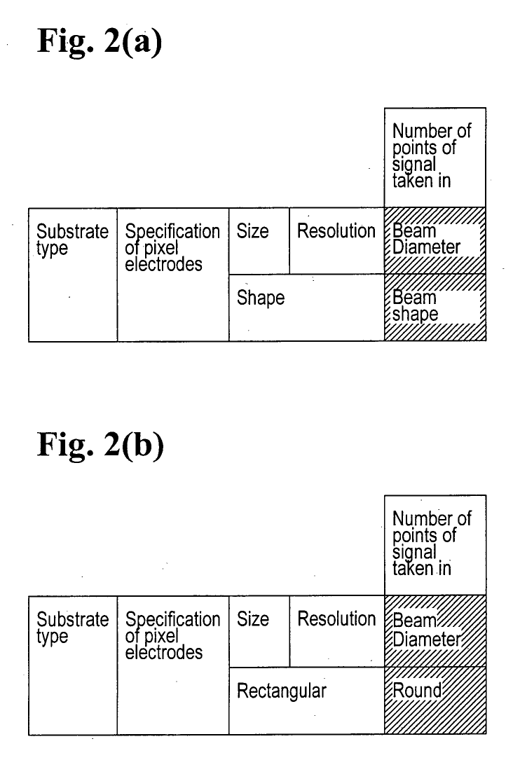

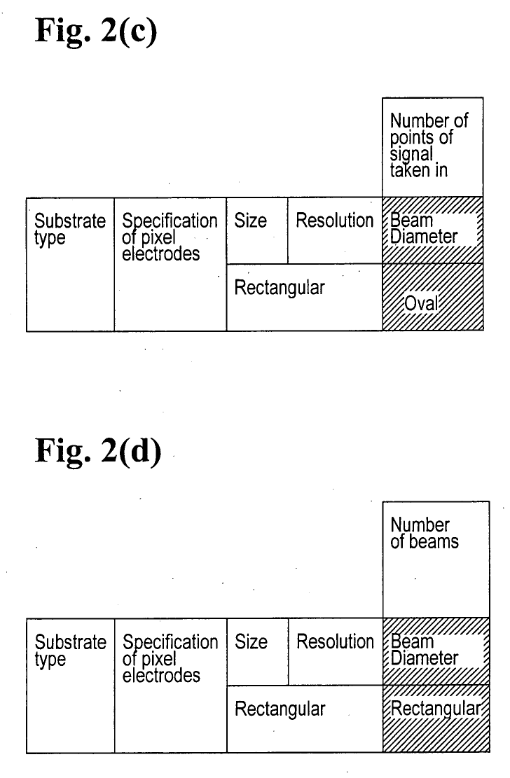

FIGS. 2(a) to 2(d) are schematic diagrams for explaining a relationship between the beam size and beam shape, and the number of the detection points and the specification of the pixel electrode. In FIGS. 2(a) to 2(d), the number of the detection points is one of factors for defining the beam size and beam shape, and the specification of the pixel electrode is another. The number of the detection points corresponds to the number of positions where the charged particle beam is irradiated on one pixel electrode, and may be set to any number such as 4, 6, 8 or 9. The number of the detection points can be set in advance as an inspection recipe for the TFT substrate, or can be set or changed in the TFT array inspection device. The charged particle beam scanning mechanism and the secondary electron detector of the TFT array inspection device control a scanning speed of the charged particle beam and a timing of detecting the secondary electrons in accordance with the number of the detection points.

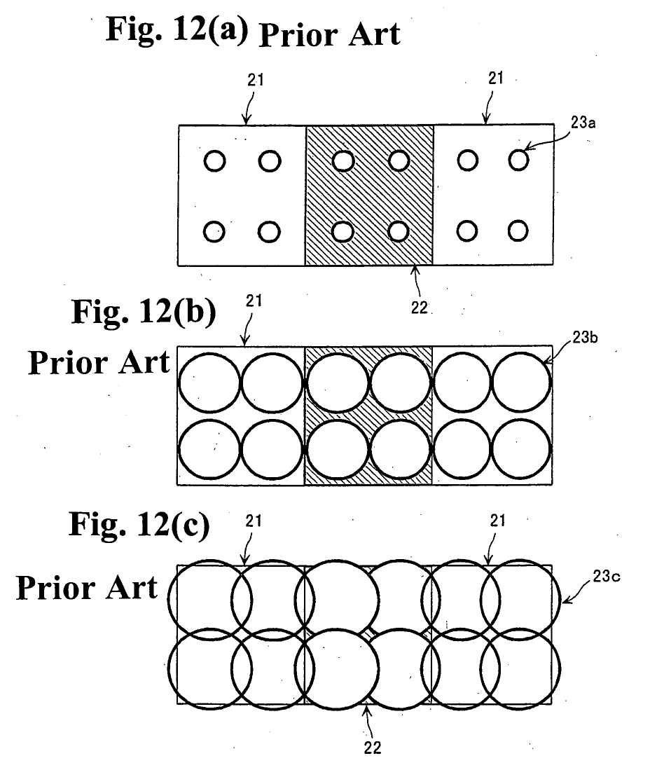

The specification of the pixel electrode includes a size and resolution of the TFT substrate as parameters as well as the setting condition of the pixel electrode. When the size and resolution of the TFT substrate are defined as the parameters, the size of the electron beam can be set to, for example, 70 microns for inspecting a 15 inch XGA standard TFT array, and 50 microns for inspecting a 17 inch SXGA standard TFT array. The beam size can be determined experimentally or theoretically from the relationship between the pixel electrode and the irradiation area of the charged particle beam shown in FIGS. 12(a) to 12(c). The beam shape includes a circular shape having a size within the shape of the pixel electrode, an elliptical shape, and a rectangular shape corresponding to a rectangular shape of the pixel electrode.

The specification of the pixel electrode can be specified according to a type of substrate. For example, in the cases of a 15 inch XGA standard TFT array and 17 inch SXGA standard TFT array, when the specification of the pixel electrode corresponds to the type of TFT substrate one-to-one, the beam data of the beam size and beam shape are specified according to the type of TFT substrate.

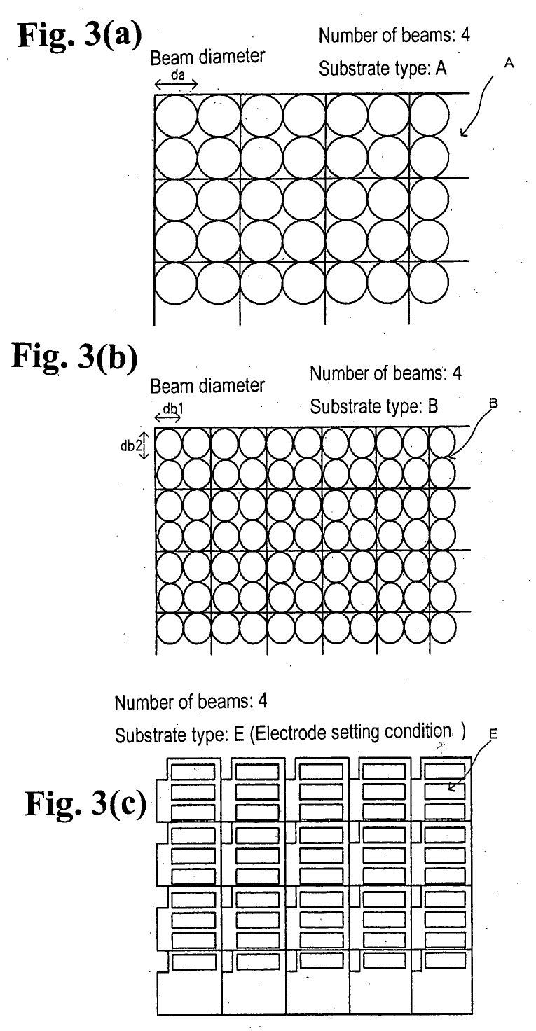

FIGS. 2(b) to 2(d) are schematic diagrams showing examples of the beam data. FIGS. 3(b) to 3(c) are schematic diagrams showing examples of the beam size and the beam shape defined according to the substrate type corresponding to FIGS. 2(b) to 2(d). In FIG. 2(b) and FIG. 3(a), the beam data of a beam size da and a round beam shape is defined for a substrate type A. In FIG. 2(c) and FIG. 3(b), the beam data of beam sizes db1 and db2 and an elliptical beam shape is defined for a substrate B. In FIG. 2(d) and FIG. 3(c), the beam data of a rectangular beam shape is defined for a substrate type C. In FIGS. 2(a) to 3(C), the number of the positions irradiated by the charged particle beam on one pixel electrode is set to four.

The signal processing device 12 inputs secondary electron detection signals from the secondary electron detector 6 with a management device 15. The signal processing device 12 also retrieves the beam data from the data table 13 and the control device 14, and stores the beam data in a data memory 16. A signal processing circuit 17 inspects a defect on the pixel electrode based on the secondary electron detection signals recorded in the data memory 16 and the beam data when the secondary electron signals are measured.

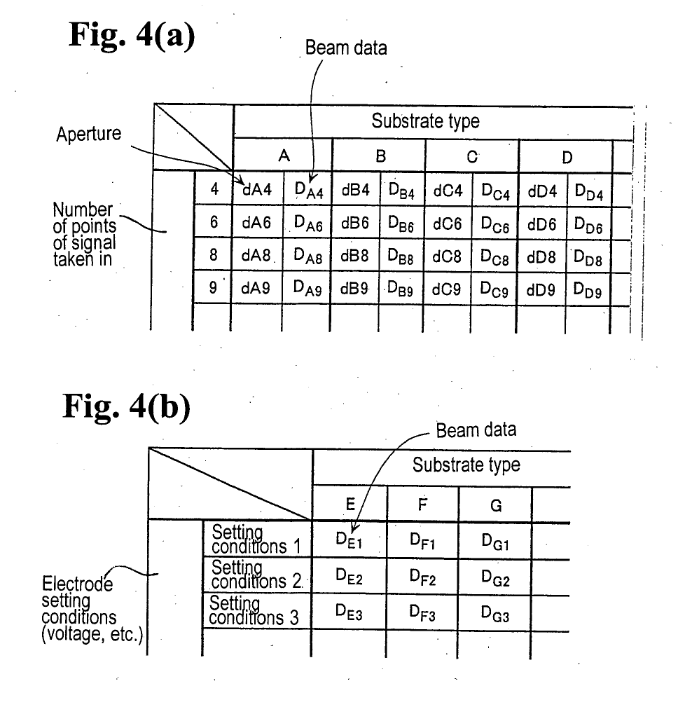

FIGS. 4(a) and 4(b) are views showing examples of the data table. FIG. 4(a) is an example of the beam size set in correspondence with the number of the detection points and the type of substrate, and FIG. 4(b) is an example of the beam shape set in accordance with the electrode setting condition and the type of substrate. The electrode setting condition includes a voltage. For example, as shown in FIG. 4(a), when the number of the detection points is four, a size dA4 and beam data DA4 are set for a substrate A, dB4 and DB4 are set for a substrate B, and dC4 and DC4 are set for a substrate C. When the number of the detection points is six, eight or nine, it is possible to set the size and beam data in the same manner. As shown in FIG. 4(b), when the electrode setting condition is defined as a setting condition 1, beam data DE1 is set for a substrate type E, beam data DF1 is set for a substrate type F, and beam data DG1 is set for a substrate type G. When the electrode setting condition is a setting condition 2, or a setting condition 3, it is possible to set the beam data in the same manner.

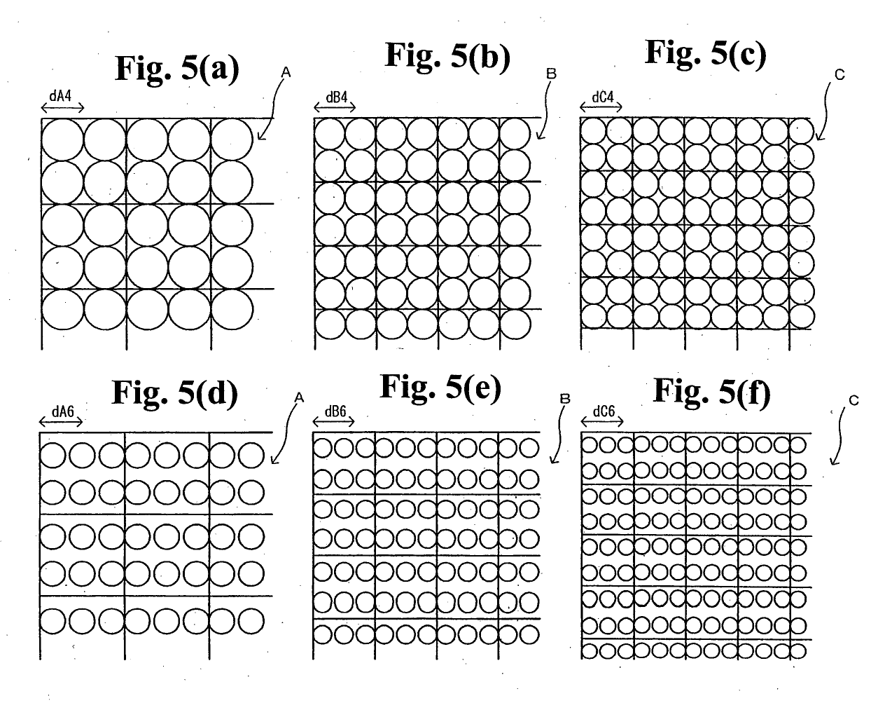

FIGS. 5(a) to 5(f) are schematic diagrams for explaining examples of the size of the charged particle beam in accordance with the number of the detection points and the substrate type. FIGS. 5(a) to 5(c) are schematic diagrams for explaining examples of a relationship between the pixel electrode and the irradiation area of the charged particle beam when the number of the detection points is four for the substrate types A, B, and C in FIG. 4(a). FIG. 5(a) is an example of the substrate A, in which the four irradiation areas with a beam diameter dA4 are situated on one pixel electrode. FIG. 5(b) is an example of the substrate B, in which the four irradiation areas with a beam diameter dB4 are situated on one pixel electrode. FIG. 5(c) is an example of the substrate type C, in which the four irradiation areas with a beam diameter dC4 are situated on one pixel electrode.

FIGS. 5(d) to 5(f) are schematic diagrams for explaining examples of a relationship between the pixel electrode and the irradiation area of the charged particle beam when the number of the detection points is six for the substrate types A, B, and C in FIG. 4(a). FIG. 5(d) is an example of the substrate type A, in which the six irradiation areas with a beam diameter dA6 are situated on one pixel electrode. FIG. 5(e) is an example of the substrate type B, in which the six irradiation areas with a beam diameter dB6 are situated on one pixel electrode. FIG. 5(f) is an example of the substrate type C, in which the six irradiation areas with a beam diameter dC6 are situated on one pixel electrode.

In the present invention, the number of the detection points and the substrate type are specified to set an optimal beam diameter in advance. Further, the secondary electron signals are detected at a specific timing, so that it is possible to obtain a specific number of the secondary electron detection signals within one pixel electrode.

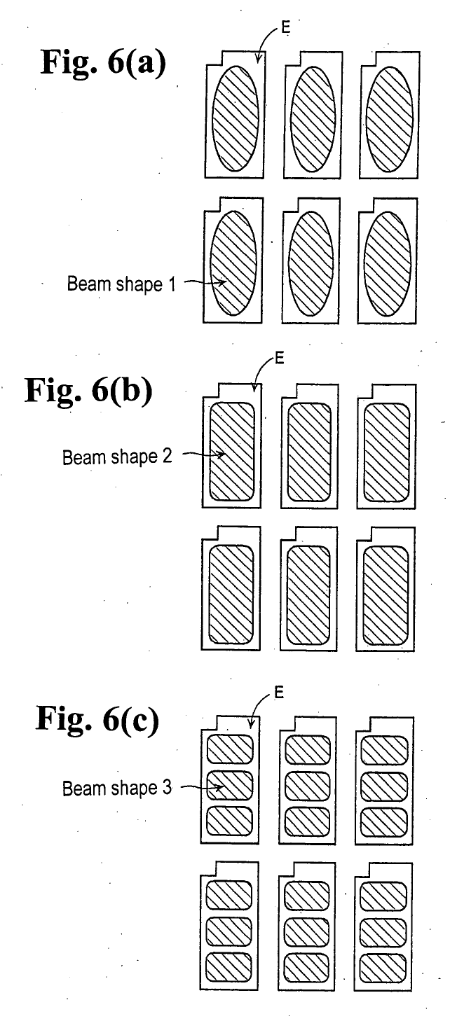

FIGS. 6(a) to 6(c) are schematic diagrams for explaining examples of the beam shape of the charged particle beam in accordance with the setting condition of the pixel electrode. FIGS. 6(a) to 6(c) are schematic diagrams for explaining examples of a relationship between the pixel electrode and the irradiation area of the charged particle beam when the substrate type is E and the setting conditions are the setting conditions 1 to 3 in FIG. 4(b). FIG. 6(a) is an example of the setting condition 1, in which the irradiation area with a beam shape 1, i.e., an elliptical shape, is situated on one pixel electrode. FIG. 6(b) is an example of the setting condition 2, in which the irradiation area with a beam shape 2, i.e., a rectangle shape, is situated on one pixel electrode. FIG. 6(c) is an example of the setting conditions 3, in which the three irradiation areas with a beam shape 3, i.e., a rectangular shape, are situated on one pixel electrode. Each of the irradiation areas may have a same shape, or a combination of rectangular shapes corresponding to shapes of locations where the TFTs are disposed and locations with no cut-out portions. The irradiation areas may have an elliptical or polygonal shape at the locations where the TFTs are arranged, or may have a rectangular shape at other locations.

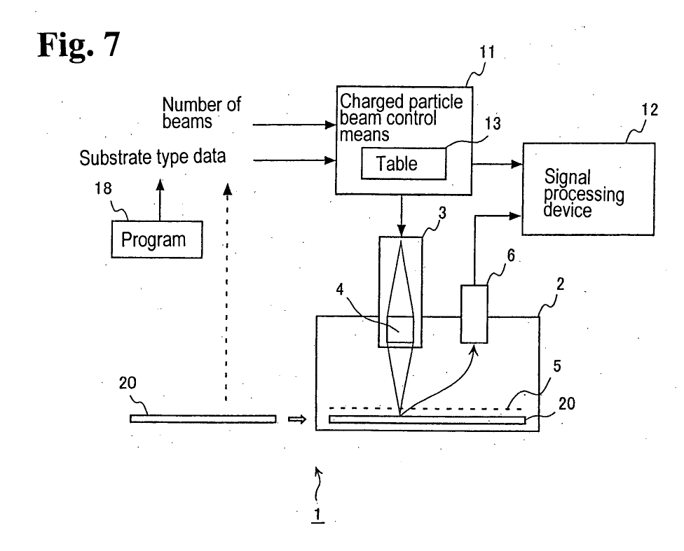

FIG. 7 is a block diagram of a configuration for setting the beam size and/or beam shape for the TFT substrate as an object of inspection. As shown in FIG. 7, in a vacuum chamber 2, a TFT array inspection device 1 includes a charged particle beam source 3 such as an electron gun; the lens system 4 formed of a slit and a magnetic field lens or electrostatic lens; an energy filter 5; and the secondary electron detector 6. The charged particle beam source 3 and the lens system 4 are controlled by the charged particle beam control device 11. The lens system 4 is controlled to form the charged particle beam in a specific shape with a specific diameter. The charged particle beam control device 11 has the data table 13 for storing the beam data for setting the beam size and beam shape in accordance with the number of the detection points or the substrate type. The charged particle beam control device 11 reads the beam data from the data table 13 based on the number of the detection points or the substrate type to control the lens system 4.

The charged particle beam passes through the lens system 4, and is radiated onto the TFT substrate 20, so that the pixel electrode of the TFT substrate is irradiated with the charged particle beam. The irradiation area of the charged particle beam on the pixel electrode is formed in a specific shape having a specific size. The secondary electron detector 6 detects the secondary electrons selected by an energy filter 5 from the secondary electrons emitted from the pixel electrode. The signal processing device 12 inputs the secondary electron detection signals from the secondary electron detector 6, and inputs the beam data for irradiating the charged particle beam from the charged particle beam control device 11. Accordingly, the position of the secondary electron signal on the pixel electrode is identified, thereby inspecting a defect of the TFT array.

The charged particle beam control device 11 obtains the number of the detection points and the substrate type from a program 18 setting an inspection process of the TFT substrate. Alternatively, a detection device may be provided in a transport path of the TFT substrate 20 for detecting identifying information provided on the TFT substrate during transport, thereby acquiring from the identifying information. The identifying information includes specific information for specifying the substrate in addition to the number of the detection points and the substrate type. When the specific information is used, the number of the detection points and the substrate type for the specific information are set in the charged particle beam control device 11 in advance, and then the number of the detection points and the substrate type are read based on the specific information.

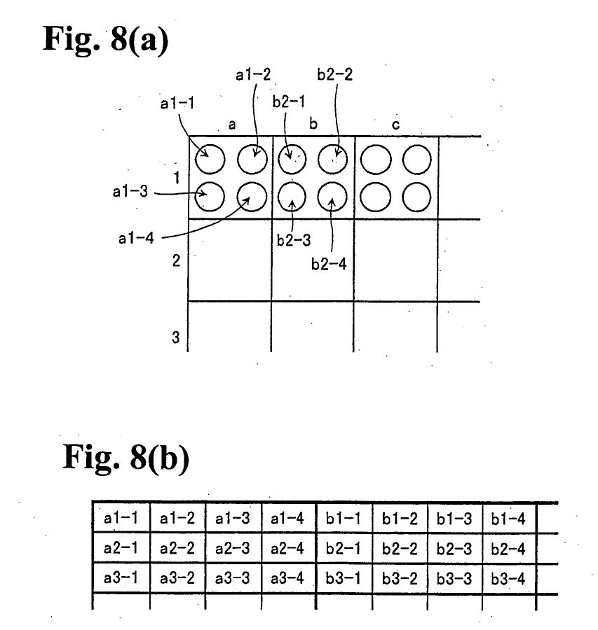

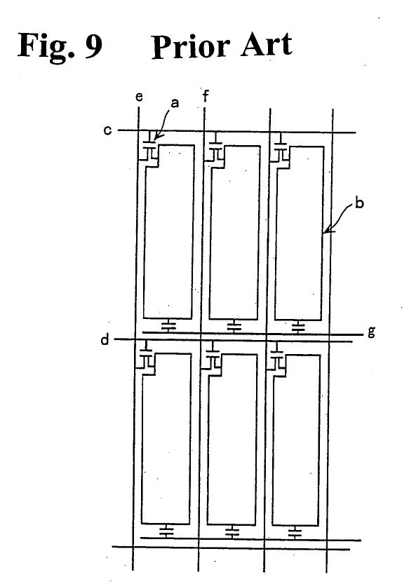

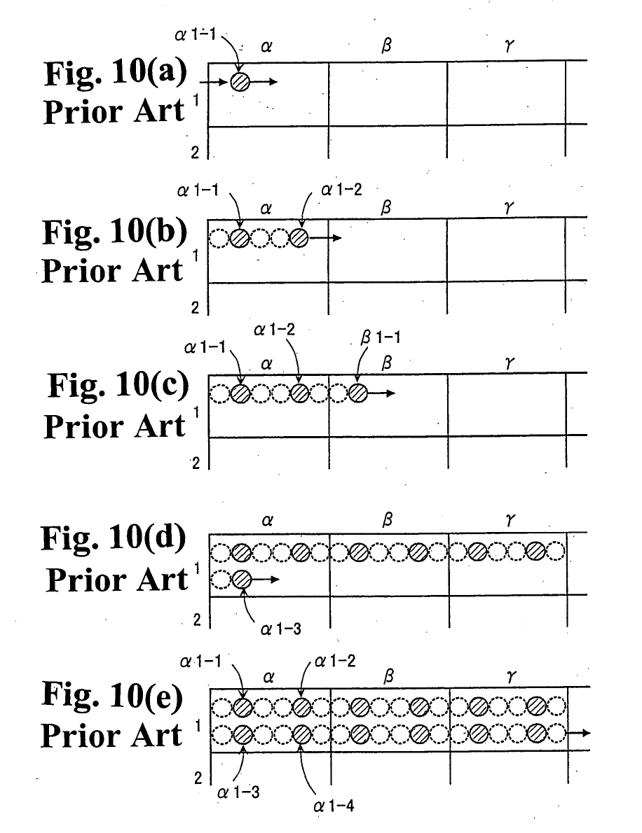

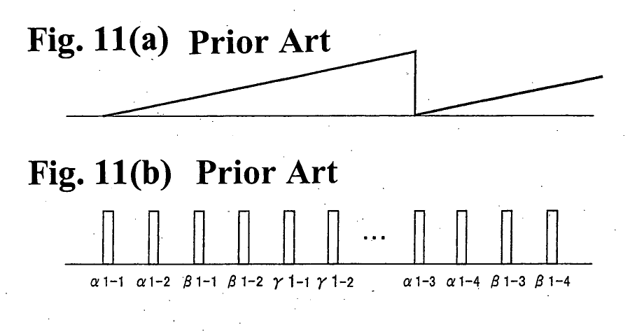

FIGS. 8(a) and 8(b) are schematic diagrams for explaining a process of recording the detection signals of the secondary electrons. FIG. 8(a) shows a relationship between the pixel electrode and the irradiation area of the charged particle beam in which the four irradiation areas are situated on one pixel electrode. In the drawing, the pixel electrode indicated by a coordinate a1 has four irradiation areas at positions indicated by a1-1, a1-2, a1-3, and a1-4, and the secondary electron detection signals are acquired from each irradiation area.

The detected secondary electron detection signals are stored in the data memory. FIG. 8(b) shows an example of a secondary electron detection signal data recorded in a data area of the data memory.

According to the present invention, the TFT array inspection device can be applied to TFT substrates used in liquid crystal displays, organic EL displays and the like.

The disclosure of Japanese Patent Application No. 2004-022820, filed on Jan. 30, 2004, is incorporated in the application.

While the invention has been explained with reference to the specific embodiments of the invention, the explanation is illustrative and the invention is limited only by the appended claims.

1. A TFT array inspection device for inspecting a TFT array, comprising:
means for irradiating a TFT substrate with a charged particle beam and detecting secondary electrons produced from a pixel electrode of the TFT substrate by irradiation of the charged particle beam, and
a charged particle beam control device for changing at least one of a size and a shape of the charged particle beam in accordance with at least one of a specification of the pixel electrode and a number of detection points on the pixel electrode.

2. A TFT array inspection device according to claim 1, wherein said charged particle beam control device includes a data table for storing beam data for defining in advance the at least one of the size and the shape corresponding to said at least one of the specification of the pixel electrode and the number of the detection points on the pixel electrode, said charged particle beam control device reading the beam data from the data table based on the at least one of the specification of the pixel electrode and the number of the detection points on the pixel electrode and controlling the at least one of the size and the shape of the charged particle beam based on the beam data.

3. A TFT array inspection device according to claim 1, wherein said charged particle beam control device changes the at least one of the size and the shape in accordance with the specification of the pixel electrodes including a parameter of at least one of a size of the TFT substrate, a resolution of the TFT substrate, and a setting condition of the pixel electrode.

4. A TFT array inspection device according to claim 1, wherein said charged particle beam control device comprises the data table identifying the specification of the pixel electrode according to the TFT substrate.

5. A TFT array inspection device according to claim 1, wherein said charged particle beam control device changes the size in accordance with the at least one of the specification of the pixel electrode and the number of the detection points on the pixel electrode when the charged particle beam has a round shape.

6. A TFT array inspection device according to claim 1, wherein said irradiating means includes a charged particle beam source disposed in a vacuum chamber for irradiating the charged particle beam on the pixel electrode, and a lens system disposed in the vacuum chamber for focusing the charged particle beam in a specific shape with a specific size.

7. A TFT array inspection device according to claim 6, further comprising a secondary electron detector disposed in the vacuum chamber for detecting a secondary electron at detection points on the pixel electrode, said charged particle beam control device being electrically connected to the lens system for changing said at least one of the specific size and the specific shape of the charged particle beam.
